(19) United States
(12) Patent Application Publication
(10) Pub. No.: US 2008/0132077 A1
(43) Pub. Date: Jun. 5, 2008

(54) Method for manufacturing a fin field effect transistor

(75) Inventor: Masato Morishima, Nirasaki City (JP)

Correspondence Address: MASUVALLEY & PARTNERS, 8765 AERO DRIVE, SUITE 312, SAN DIEGO, CA, 92123, US

(73) Assignee: TOKYO ELECTRON LIMITED, Tokyo (JP)

(21) Appl. No.: 11/999,224

(22) Filed: Dec. 3, 2007

(30) Foreign Application Priority Data
Dec. 5, 2006 (JP) JP2006-327924

(51) Int. Cl. H01L 21/306

(52) U.S. Cl. 438/704; 257/E21.215

(57) ABSTRACT

The objective of the present invention is to provide a manufacturing method of a fin field effect transistor easily and surely without a constriction on a bottom end portion of the fin, through a method that includes a process for removing damage caused by plasma etching by wet etching of a sacrificial oxide film using a SOI wafer. The method of the present invention includes a process for forming a projection in a fin shape by plasma etching a single crystal silicon layer on a SOI wafer, forming a sacrificial oxide film on the surface including anticipated damage to the projection, a process for removing the sacrificial oxide layer by wet etching, and a reflow process to reflow the buried oxide layer by heating.

### TECHNICAL FIELD

The present invention relates to a method for manufacturing a fin field effect transistor using a SOI (Silicon on Insulator) wafer.

### BACKGROUND OF THE INVENTION

In the recent years, the degree of integration of integrated circuits is becoming increasingly high, and the miniaturization of a field effect transistor (FET) used in an integrated circuit, such as CMOS, has been desired. For this reason, shortening of the channel length, a decrease of the thickness of a gate insulating film, and an increase of impurity doping concentration and so on have been attempted. However, the shortening of the channel length is reaching the limit, which makes it difficult to miniaturize while maintaining the current structure.

As a technique capable of resolving such issues and further realizing miniaturization and high integration of the field effect transistor, a three-dimensional type field effect transistor, in which forming a projection in a fin shape on a Si wafer and forming a channel face vertically, so called fin field effect transistor has been known (For example, Japanese Published Unexamined Patent Application No. 2005-528793).

Meanwhile, a leak current of the field effect transistor in the off state is becoming an issue with the high integration of the integrated circuits, thus a SOI wafer, which can decrease such leak current, has come into use. The SOI wafer is a buried Oxide layer consisting of a silicone oxide formed on a single crystal silicon substrate wafer, with a single crystal silicone layer grown thereon. The technique to form the fin field effect transistor described above on such a SOI wafer is disclosed in Japanese Published Unexamined Patent Application No. 2003-528448.

When manufacturing a fin field effect transistor, the following method is generally used to form a fin. First, form a projection in a fin shape by performing plasma etching to a wafer. This projection is in a size larger than the final fin form. However, since damage is caused by the plasma to the surface of this projection, form a sacrificial oxide film by oxidizing the surface including the damage as a next process, and then form a fin, which has a clean surface, in a smaller size (virtually the same size as of the final form) than the projection that is formed first by removing the sacrificial oxide film by the wet etching method that uses a dilute fluorinated acid.

In this way, the method for removing the damage caused from the plasma etching by the wet etching of the sacrificial oxide film is easy to operate and is capable of forming a fin in a size (for example, the width of 30 nm to 40 nm) that can not be formed by the plasma etching only.

However, in a case when the SOI wafer described above is used as a wafer, that is, in a case when forming a projection in a fin shape by performing the plasma etching to a single crystal silicone layer on the buried oxide layer, and removing the damage caused to this projection by the wet etching of the sacrificial oxide film, a constriction (i.e., an overhang) 52 occurs to the bottom end portion of the fin 51 formed as shown in FIG. 6.

This constriction 52 is formed as follows. That is, the wet etching is performed on the upper portion of the buried oxide layer 53, which is exposed by the plasma etching, along with the sacrificial layer by the dilute fluorinated acid (the buried oxide layer before the wet etching is indicated in a dotted line). Further, the constriction is formed because the silicon oxide right below (not exposed) the fin 51 is also partially etched (side etching) due to the isotropism of the wet etching.

And, when such a constriction occurs, the residue of gate wiring material and so on occur on that portion and it may cause adverse affects to the device performance. Conventionally, removal of such residue by chemical cleansing has been attempted. However, the cleansing process is complicated, and it is difficult to remove these residues completely by the cleansing process. Further, when such constriction occurs, an issue of strength, such as falling of the fin, is also a concern.

### SUMMARY OF THE INVENTION

The present invention has been made considering the above situations, and the present invention including a process for removing the damage caused from the plasma etching using a SOI wafer by wet etching of a sacrificial oxide film. And the objective of the present invention is to provide a method for manufacturing a fin field effect transistor easily and surely without a constriction on the bottom end portion of the fin.

In order to solve the issues described above, the present invention provides a method for manufacturing a fin field effect transistor using a SOI wafer, which including a buried oxide layer consisting of a SIO₂ material that is formed on a Si substrate and a single crystal silicon layer is further formed thereon. The manufacturing method includes: a process for forming a projection in a fin shape by selectively performing plasma etching on the single crystal silicon layer until the underlying buried oxide layer exposes; a process for forming a sacrificial oxide film oxidizing the surface including the damage occurred to the projection; a process for forming a fin having a clean surface by removing this sacrificial oxide film by wet etching; and a reflow process for reflowing the buried oxide layer by heating.

In the present invention, it is preferable to use the buried oxide layer consisting of a SiO₂ based material, in which impurities, such as phosphorus and boron and so on, are added to lower the melting point, and specially, it is preferable to use a Borophosphosilicate Glass (BPSG) containing phosphorus and boron as the impurities.

In a case when the buried oxide layer consists of BPSG in the reflow process described above, the BPSG may be reflowed by heating to a temperature of 900 degree/C. or below, for example, 800 degree/C.±100 degree/C.

In the present invention, the width (Wo) of the projection formed by the plasma etching process is 60 nm to 80 nm, and the width (W) of the fin formed finally may be 30 nm to 40 nm. At this time, the ratio (Wo/W) may be 1.5 to 2.0. Also, dilute fluorinated acid may be used as an etching solution when removing the sacrificial film.

According to the manufacturing method of the present invention, by adding the process to heat and reflow the buried oxide layer, the fin field effect transistor without a constriction on the bottom end portion of the fin can be manufactured easily and surely, through a manufacturing method that includes a process for removing the damage from the plasma etching by the wet etching of the sacrificial oxide film utilizing a SOI wafer.

### BRIEF DESCRIPTION OF THE DRAWINGS

FIG. 1 is a cross-sectional process diagram showing a manufacturing method according to the present invention.

FIG. 2 is a cross-sectional process diagram showing a manufacturing method according to the present invention.

FIG. 3 is a cross-sectional process diagram showing a manufacturing method according to the present invention.

FIG. 4 is a cross-sectional process diagram showing a manufacturing method according to the present invention.

FIG. 5 is a cross-sectional process diagram showing a manufacturing method according to the present invention.

FIG. 6 is a cross-sectional diagram showing a condition where a constriction is located on a bottom end portion of a fin by a conventional manufacturing method.

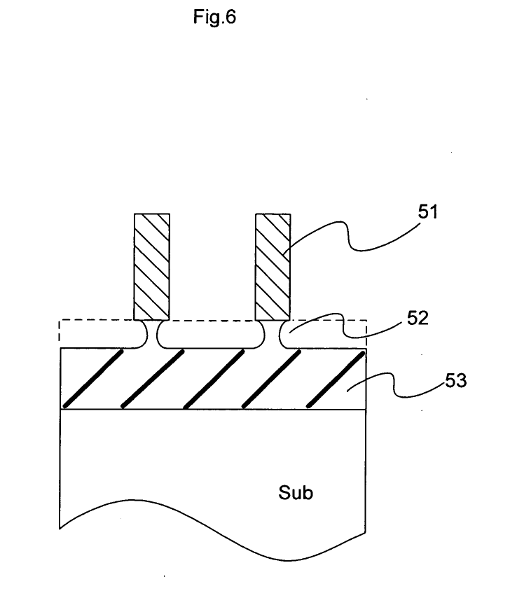

### DETAILED DESCRIPTION OF THE INVENTION

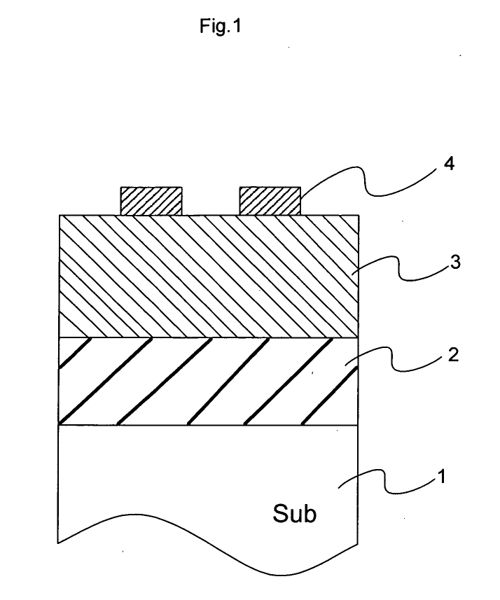

An embodiment of the present invention is hereinafter explained. FIGS. 1 to 5 are cross-sectional process diagrams showing a manufacturing method for a fin field effect transistor according to the present invention. This manufacturing method is a manufacturing method using a SOI wafer, and the method includes: a process for forming a projection by plasma etching; a process for forming a sacrificial oxide film on the projection; a process for removing the sacrificial oxide film by wet etching; and a process for reflowing a buried oxide layer.

In this embodiment, first, prepare a SOI wafer in a layer constitution as shown in FIG. 1. In this SOI wafer, laminated are a silicon substrate 1 consisting of a single crystal silicon, a buried oxide layer 2 consisting of a SiO₂ based material, and a single crystal silicon layer 3.

For the buried oxide layer 2, it is preferable to utilize a SiO₂ based material, in which one or two, or more impurities, such as phosphorus or boron, are added. By containing the impurities, such as phosphorus or boron, the melting point of the oxide in the buried oxide layer 2 can be decreased, thereby the heating temperature at a reflow process can be decreased. From this standpoint, a BPSG (Borophosphosilicate Glass), which contains boron and phosphorus, can be favorably used as the SiO₂ based material that constitutes the buried oxide layer 2.

The film thickness of the buried oxide layer 2 is, for example, approximately 130 nm to 160 nm. In this range, the leakage current when the field effect transistor is in an off state can be sufficiently suppressed. The film thickness of the single crystal silicon layer 3 on the buried oxide layer 2 prescribes the height of the fin, which when in final form is, for example, approximately 50 nm to 100 nm.

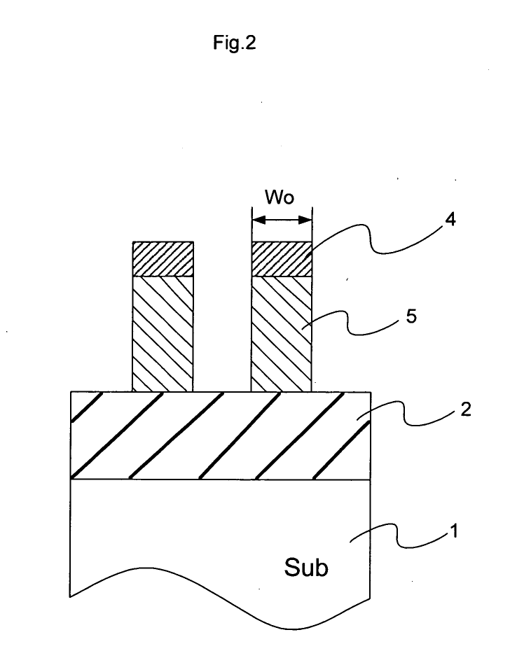

In the plasma etching process, the plasma etching is performed after forming a pattern of a hard mask 4 on the single crystal silicon layer 3. In this way, the single crystal silicone layer 3 is selectively scraped, and a portion of the buried oxide layer 2 is exposed, thereby a projection 5 in a fin shape is formed as shown in FIG. 2.

The plasma etching process is not limited specifically, and it may be performed according to an ordinary method using a conventionally known apparatus. Since a damage layer is formed at the plasma etching, it is preferable to predetermine the width of the projection 5 to be larger than the width of the fin, in order to secure the scraping margin when removing the damage layer.

For example, in a case when forming a fin with a width (W) of approximately 30 nm to 40 nm, the width (Wo) of the projection formed in the plasma etching process is preferably approximately 60 nm to 80 nm. In such a case, the ratio (Wo/W) of the width (Wo) of the projection against the width (W) of the fin is preferably approximately 1.5 to 2.0.

When the ratio (Wo/W) is below 1.5, the scraping margin can not be sufficiently secured for the removal of the damage layer at the wet etching by forming a sacrificial oxide layer described later. Meanwhile, in a case when the ratio (Wo/W) exceeds 2.0, the scraping margin becomes excessive, thereby the removal of the sacrificial oxide film may take longer or the etching of the buried oxide layer may progress excessively.

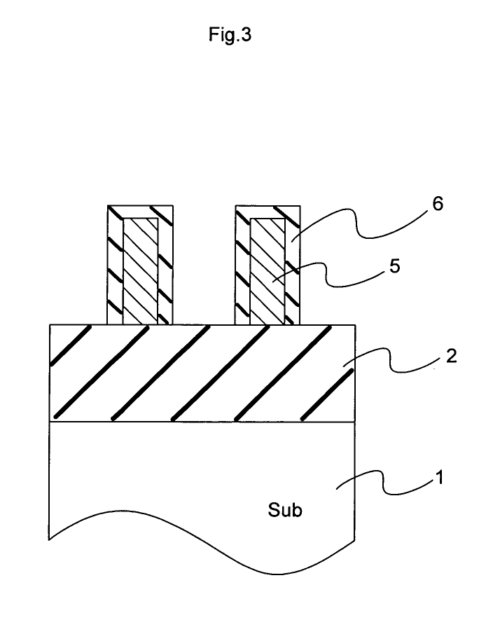

After finishing the plasma etching process, perform a sacrificial oxidation process by removing the hard mask 4. In the sacrificial oxidation process, a sacrificial oxide film 6 as shown in FIG. 3 is formed by oxidizing the surface of the projection 5 including the damage. The method for forming the sacrificial oxide film 6 is not specifically limited, and it may be formed by a known method using a conventionally known apparatus. For example, the thermal oxidation method, in which heating under the existence of the oxidation gas, may be utilized.

In order to form a fin with a clean surface in the subsequent wet etching process, the sacrificial oxide film 6 is necessary to have the film thickness that can contain the area (damage layer) where the damage of the projection 5 exists. The film thickness of the sacrificial oxide film 6 is, for example, approximately 30 nm to 40 nm, and this film thickness can be adjusted as needed by controlling the oxidation process conditions.

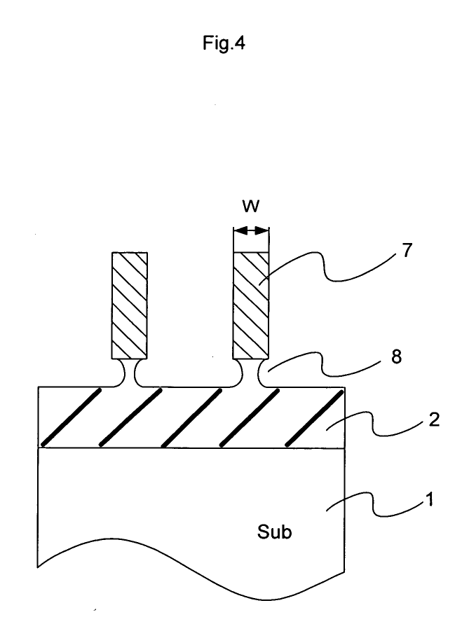

In the wet etching process, the sacrificial oxide film 6 is removed by the wet etching as shown in FIG. 4. As an etching solution, the silicon oxide is capable of etching, however, the selection is made from the solutions that do not etch the single crystal silicon (i.e., do not damage the base which then becomes the fin). More specifically, it is preferable to utilize a solution of fluorinated acid (HF), which is widely used in this field conventionally, and more preferable to utilize a dilute fluorinated acid (HF concentration=1 to 5 percent by mass).

By removing the sacrificial oxide film 6, the damage occurring on the surface of the projection 5 by the plasma etching is removed, and a fin 7 with a clean surface is formed on the buried oxide layer 2. The width (W) of the fin 7 formed in this way is, for example, approximately 30 nm to 40 nm.

By the way, in the wet etching after forming the sacrificial oxide film 6, the buried oxide layer is also etched along with the sacrificial oxide film 6 as described above. Since the etching at this time is isotropic, and not only the exposed portion of the buried oxide layer but also the non-exposed portion is etched (side etching), a constriction 8 inevitably occurs on the bottom end portion of the formed fin 7.

Consequently, in this embodiment, such constriction is eliminated by performing a reflow process, in which heat and reflow of the buried oxide layer 2 is performed, after the wet etching process. In the reflow process, the heating temperature is equal or greater than the melting point of the SiO₂, based material constituting the buried oxide layer 2. For example, in a case when the buried oxide layer 2 consists of SiO₂, which does not add any impurities, the heating temperature is approximately 1000 degree/C. to 2000 degree/C.

However, because such high temperature may cause various inconveniences in the processes, it is preferable to decrease the heating temperature of the reflow process by using a SiO₂ based material, to which is added one, or two or more impurities, such as phosphrus or boron, as the buried oxide layer 2 to lower the melting point as described above. Specially, in a case when the BPSG is utilized as a SiO2 based material, the buried oxide layer 2 can be reflowed at a low heating temperature, such as approximately 900 degree/C. or below. A more preferable temperature is around approximately 800 degree/C. (800 degree/C.+/−100 degree/C.).

The heat processing in the reflow process is normally performed under an atmosphere of inert gas, such as nitrogen gas. The pressure during processing is not specifically limited, and it may be performed for example, at approximately 100 Torr to 500 Torr (approximately 13330 Pa to 66650 Pa). Also, the processing time is approximately 30 to 300 second.

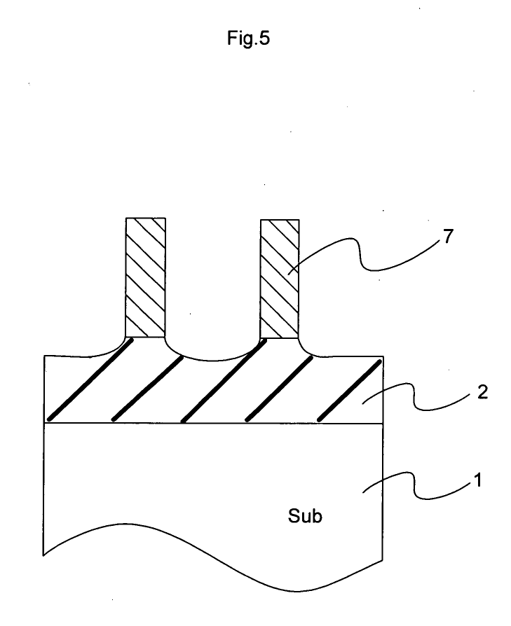

By performing the reflow to the buried oxide layer 2 in this way, the buried oxide layer 2 flows and the reflowed silicon oxide inflows to the constriction of the bottom end portion of the fin, or the bottom end portion of the fin sinks into the reflowed buried oxide layer 2. And, the constriction completely disappears as shown in FIG. 5, and the buried oxide layer 2 is solidified in a condition that the constriction is eliminated by cooling thereafter. For this reason, the fin 7 is securely retained by the buried oxide layer 2.

After eliminating the constriction by such a reflow process, other processes can be performed, such as forming gate wiring, or forming a diffusion region, according to the ordinary method, thereby obtaining a desirable fin field effect transistor.

In this way, there is no constriction on the bottom end portion of the fin 7 of the fin field effect transistor manufactured by this embodiment, thus an adverse effect to the device performance resulting from the gate wiring material and so on remaining on the constriction does not occur. Also, the fin 7 is securely retained by the buried oxide layer 2, thus the problem relating to strength, such as the fin falling down, does not occur.

What is claimed is:

1. A method for manufacturing a fin field effect transistor using a SOI wafer comprising a buried oxide layer including a SiO₂ based material formed on a Si substrate, and a single crystal silicon layer further formed thereon, the method comprising the steps of:
forming a projection in a substantial fin shape by selectively performing a plasma etching on the single crystal silicon layer until the buried oxide layer is exposed;
forming a sacrificial oxide film by oxidizing a surface of the substantial fin shape including an anticipated damage occurring to the projection;
forming a fin having a clean surface by removing the sacrificial oxide film by a wet etching; and
reflowing the buried oxide layer by heating.

2. The method for manufacturing the fin field effect transistor according to claim 1, wherein the buried oxide layer is comprised of a SiO₂ based material, in which an impurity is added to lower a melting point.

3. The method for manufacturing the fin field effect transistor according to claim 1, wherein the SiO₂ base material comprising the buried oxide layer is a Borophosphosilicate Glass containing a phosphorus and a boron as impurities.

4. The method for manufacturing the fin field effect transistor according to the claim 1, wherein the reflowing step includes a step that a Borophosphosilicate Glass is reflowed by heating to a temperature of about 900 degree/C. or below.

5. The method for manufacturing the fin field effect transistor according to the claim 1, wherein the reflowing step includes a step that a Borophosphosilicate Glass is reflowed by heating to a temperature of about 800 degree/C.±100 degree/C.

6. The method for manufacturing the fin field effect transistor according to claim 1, wherein a width (Wo) of the projection formed by the plasma etching is about 60 nm to 80 nm, and a width (W) of the fin in a final form is approximately 30 nm to 40 nm.

7. The method for manufacturing the fin field effect transistor according to claim 6, wherein a ratio (Wo/W) of the width (Wo) of the projection formed by the plasma etching process against the width (W) of the fin in a final form is about 1.5 to 2.0.

8. The method for manufacturing the fin field effect transistor according to claim 1, wherein a dilute fluorinated acid is used as the wet etching solution when removing the sacrificial oxide film.

9. A method for manufacturing a fin field effect transistor by forming a buried oxide layer including a SiO₂ based component on a Si substrate, and further forming a single crystal silicone layer on the buried oxide layer, the method comprising the steps of
plasma etching the single crystal silicone layer to form a projection from the buried oxide layer;
oxidizing the projection to form a sacrificial oxide film on a surface of the projection;
wet etching the sacrificial oxide film; and
heating the buried oxide layer.

10. The method for manufacturing the fin field effect transistor according to claim 9, wherein the buried oxide layer includes a SiO₂ component containing an impurity.

11. The method for manufacturing the fin field effect transistor according to claim 10, wherein the impurity is a phosphorus or a boron.

12. The method for manufacturing the fin field effect transistor according to claim 11, wherein a heating temperature in the heating step of is about 900 degree/C. or below.

13. The method for manufacturing the fin field effect transistor according to claim 9, wherein a width (Wo) of the projection after the plasma etching step is about 60 nm to 80 nm, and a width (W) of the projection after heating the buried oxide layer is about 30 nm to 40 nm.

14. The method for manufacturing the fin field effect transistor according to claim 13, wherein a ratio (Wo/W) of the width (Wo) against the width (W) is about 1.5 to 2.0.
